(19) United States
(12) Patent Application Publication
(10) Pub. No.: US 2023/0317464 A1
(43) Pub. Date: Oct. 5, 2023

(54) Surface Treatment Compositions and Methods

(71) Applicant: Fujifilm Electronic Materials U.S.A., Inc., N. Kingstown, RI (US)

(72) Inventor: Jieying Jiao, Chandler, AZ (US)

(21) Appl. No.: 18/116,437

(22) Filed: Mar. 2, 2023

Related U.S. Application Data
(60) Provisional application No. 63/325,692, filed on Mar. 31, 2022.

(51) Int. Cl. H01L 21/3105; H01L 21/02

(52) U.S. Cl. CPC H01L 21/3105; H01L 21/0206

(57) ABSTRACT

This disclosure relates to methods and compositions for treating a semiconductor substrate having a pattern disposed on a surface of the substrate.

### CROSS-REFERENCE TO RELATED APPLICATION

The present application claims priority to U.S. Provisional Application Ser. No. 63/325,692, filed on Mar. 31, 2022, the contents of which are hereby incorporated by reference in their entirety.

### FIELD OF THE DISCLOSURE

The present disclosure relates generally to surface treatment, as well as related compositions and methods.

### BACKGROUND OF THE DISCLOSURE

At sub-20 nm critical dimensions, pattern collapse of FinFET's and dielectric stacks during wet clean and drying has become a major problem in semiconductor manufacturing processes. The conventional theory of pattern collapse implicates high capillary forces during rinse and dry as major contributors leading to the collapse phenomenon. However, other chemical and substrate properties may play an important role as well, namely, liquid surface tension and viscosity, substrate mechanical strength, pattern density and aspect ratio, and cleaner chemistry damage to substrate surfaces.

### SUMMARY OF THE DISCLOSURE

It has been found that certain surface treatment compositions can treat the pattern on a surface of a semiconductor substrate (e.g., a wafer such as a silicon or copper wafer) to reduce the capillary forces that drive pattern collapse during a subsequent semiconductor manufacturing process.

In one aspect, this disclosure features a method for treating a semiconductor substrate having a pattern disposed on a surface of the wafer, that method including contacting the surface with a surface treatment composition containing at least one polar organic solvent and at least one ester selected from the group consisting of sulfonic acid esters, sulfuric acid esters, and phosphoric acid esters;

in which the pattern comprises a feature having a dimension of at most about 50 nm.

In another aspect, this disclosure features a composition that includes (1) at least one polar organic solvent in an amount of from about 90 wt % to about 99 wt % of the composition; and (2) at least one ester selected from the group consisting of sulfonic acid esters, sulfuric acid esters, and phosphoric acid esters, the at least one ester being in an amount of from about 1 wt % to about 10 wt % of the composition.

In still another aspect, this disclosure features a composition consisting of (1) at least one polar organic solvent; and (2) at least one ester selected from the group consisting of sulfonic acid esters, sulfuric acid esters, and phosphoric acid esters.

Other features, objects, and advantages of the invention will be apparent from the description and the claims.

### DETAILED DESCRIPTION OF THE DISCLOSURE

As defined herein, unless otherwise noted, all percentages expressed should be understood to be percentages by weight to the total weight of a composition. Unless otherwise noted, the properties mentioned here are measured at atmospheric pressure. The term “solvent” mentioned herein, unless otherwise noted, refers to a single solvent or a combination of two or more (e.g., three or four) solvents. In the present disclosure, “ppm” means “parts-per-million”, “ppb” means “parts-per-billion” and “ppt” means “parts-per-trillion”.

In some embodiments, this disclosure relates to surface treatment methods. Such methods can be performed, for example, by contacting the surface (e.g., a surface that has patterns) of a substrate (e.g., a semiconductor substrate such as a silicon or copper wafer) with a surface treatment composition that includes at least one (e.g., two, three, or four) polar organic solvent and at least one (e.g., two, three, or four) ester selected from the group consisting of sulfonic acid esters, sulfuric acid esters, and phosphoric acid esters. The pattern can include a feature having a dimension of at most about 50 nm.

In some embodiments, semiconductor substrate that can be treated by the surface treatment composition described herein can be constructed of silicon, silicon germanium, silicon nitride, copper, Group III-V compounds such as GaAs, or any combination thereof. In some embodiments, the semiconductor substrate can be a silicon wafer, a copper wafer, a silicon dioxide wafer, a silicon nitride wafer, a silicon oxynitride wafer, a carbon doped silicon oxide wafer, a SiGe wafer, or a GaAs wafer. The semiconductor substrate can additionally contain exposed integrated circuit structures such as interconnect features (e.g., metal lines and dielectric materials) on its surfaces. Metals and metal alloys used for interconnect features include, but are not limited to, aluminum, aluminum alloyed with copper, copper, titanium, tantalum, cobalt, nickel, silicon, polysilicon, titanium nitride, tantalum nitride, tin, tungsten, ruthenium, germanium, SnAg, SnAg/Ni, CuNiSn, CuCoCu, and/or CoSn. The semiconductor substrate can also contain layers of interlayer dielectrics, silicon oxide, silicon nitride, titanium nitride, silicon carbide, silicon oxide carbide, silicon oxide nitride, titanium oxide, tantalum nitride, tantalum oxide, tantalum oxide nitride, and/or carbon doped silicon oxides.

In some embodiments, the semiconductor substrate surface to be treated by the surface treatment compositions described herein includes features containing SiO₂, SiN, TiN, SiOC, SiON, Si, SiGe, Ge, Ru, Ta, TaO, TaON, and/or W. In some embodiments, the substrate semiconductor surface includes features containing SiO₂ and/or SiN.

In general, the semiconductor substrate surface to be treated by the surface treatment compositions described herein includes patterns formed by a prior semiconductor manufacturing process (e.g., a lithographic process including applying a photoresist layer, exposing the photoresist layer to an actinic radiation, developing the photoresist layer, etching the semiconductor substrate beneath the photoresist layer, and/or removing the photoresist layer). In some embodiments, the patterns on the substrate surface can include a patterned developed photoresist layer, a patterned barrier layer, a patterned multi-stack layer, or a patterned dielectric layer. In some embodiments, the patterns can include features having at least one (e.g., two or three) dimension (e.g., a length, a width, a depth, or a line-space dimension) of at most about 50 nm (e.g., at most about 40 nm, at most about 30 nm, at most about 20 nm, at most about 15 nm, at most about 10 nm, or at most about 5 nm) and/or at least about 1 nm (e.g., at least about 2 nm or at least about 5 nm).

In some embodiments, the surface treatment compositions described herein can include at least one (two, three, or four) ester. In some embodiments, the ester can be selected from the group consisting of sulfonic acid esters, sulfuric acid esters, and phosphoric acid esters. In some embodiments, the ester can be sulfonic acid ester (or a sulfonate ester) of the following formula: R(SO₂)(OR), in which each R independently is C₁-C₁₀ alkyl (e.g., methyl or ethyl), phenyl, or C₇-C₁₀ arylalkyl. In some embodiments, the ester can be sulfuric acid ester (or a sulfate ester) of the following formula: (RO)ₙ(HO)₂₋ₙ(SO₂), in which n is 1 or 2, and each R independently is C₁-C₁₀ alkyl (e.g., methyl or ethyl), phenyl, or C₇-C₁₀ arylalkyl. In some embodiments, the ester can be phosphoric acid ester (or a phosphate ester) of the following formula: (RO)ₙ(HO)₃₋ₙP═O, in which n is 1 or 2, and each R independently is C₁-C₁₀ alkyl (e.g., methyl or ethyl), phenyl, or C₇-C₁₀ arylalkyl. Examples of suitable esters include dimethyl sulfate, diethyl sulfate, ethyl methanesulfonate, ethyl benzenesulfonate, ethyl dihydrogen phosphate, diethyl hydrogen phosphate, or triethyl phosphate.

In some embodiments, the at least one ester can be from at least about 1 wt % (e.g., at least about 1.5 wt %, at least about 2 wt %, at least about 2.5 wt %, at least about 3 wt %, at least about 3.5 wt %, at least about 4 wt %, at least about 4.5 wt %, or at least about 5 wt %) to at most about 10 wt % (e.g., at most about 9.5 wt %, at most about 9 wt %, at most about 8.5 wt %, at most about 8 wt %, at most about 7.5 wt %, at most about 7 wt %, at most about 6.5 wt %, at most about 6 wt %, at most about 5.5 wt %, or at most about 5 wt %) of the surface treatment compositions described herein. Without wishing to be bound by theory, it is believed that, in some embodiments, the surface treatment composition including the ester and organic solvent described herein can form an azeotropic mixture (e.g., a minimum boiling azeotropic mixture), which can reduce or minimize the pattern collapse during the removal of the surface treatment composition.

In some embodiments, the surface treatment compositions described herein can include at least one (two, three, or four) polar organic solvent. In some embodiments, the organic solvent can be a polar protic organic solvent, such as an alcohol (e.g., an alkanol). In some embodiments, the organic solvent can be a C₁-C₆ alkanol, such as methanol, ethanol, or isopropyl alcohol. In some embodiments, the organic solvent can be a polar aprotic solvent, such as a ketone (e.g., acetone or butanone), a lactone (e.g., butyrolactone), or a sulfoxide (e.g., dimethyl sulfoxide (DMSO)). In some embodiments, the organic solvent is selected from those capable of forming an azeotropic mixture (e.g., a minimum boiling azeotropic mixture) with the ester described herein.

In some embodiments, the organic solvent should have a boiling point sufficiently low so that it can be removed by heating without negatively impact the substrate to be treated by the surface treatment compositions described herein. In some embodiments, the organic solvent can have a boiling point of at most about 150° C. (e.g., at most about 140° C., at most about 120° C., or at most about 100° C.) under atmospheric pressure.

In some embodiments, the at least one organic solvent can be from at least about 90 wt % (e.g., at least about 90.5 wt %, at least about 91 wt %, at least about 91.5 wt %, at least about 92 wt %, at least about 92.5 wt %, at least about 93 wt %, at least about 93.5 wt %, at least about 94 wt %, at least about 94.5 wt %, or at least about 95 wt %) to at most about 99 wt % (e.g., at most about 98.5 wt %, at most about 98 wt %, at most about 97.5 wt %, at most about 97 wt %, at most about 96.5 wt %, at most about 96 wt %, at most about 95.5 wt %, or at most about 95 wt %) of the surface treatment compositions described herein.

In some embodiments, the surface treatment compositions described herein can specifically exclude or substantially free of one or more of the additive components, in any combination, if more than one. Such components are selected from the group consisting of non-aromatic hydrocarbons, certain polar organic solvents (e.g., alcohols (such as C₁-C₆ alkanol), lactones (e.g., those with 5- or 6-membered rings), or ethers), Si-containing compounds (e.g., siloxanes such as disiloxanes; silanes; silazanes such as disilazanes, cyclic silazanes or heterocyclic silazanes; and those having a Si—H group or an aminosilyl group), polymers (e.g., non-ionic, cationic, or anionic polymers), oxygen scavengers, quaternary ammonium compounds (e.g., salts or hydroxides), bases (such as alkaline bases (e.g., NaOH, KOH, LiOH, Mg(OH)₂, and Ca(OH)₂)), surfactants, defoamers, fluorine-containing compounds (e.g., HF, H₂SiF₆, H₂PF₆, HBF₄, NH₄F, tetraalkylammonium fluoride, fluoride compounds, or fluorinated compounds (such as fluorinated polymers/surfactants)), nitrogen-containing compounds (e.g., amino acids, amines, imines (e.g., amidines such as 1,8-diazabicyclo[5.4.0]-7-undecene (DBU) and 1,5-diazabicyclo[4.3.0]non-5-ene (DBN)), amides, or imides), oxidizing agents (e.g., peroxides, hydrogen peroxide, ferric nitrate, potassium iodate, potassium permanganate, nitric acid, ammonium chlorite, ammonium chlorate, ammonium iodate, ammonium perborate, ammonium perchlorate, ammonium periodate, ammonium persulfate, tetramethylammonium chlorite, tetramethylammonium chlorate, tetramethylammonium iodate, tetramethylammonium perborate, tetramethylammonium perchlorate, tetramethylammonium periodate, tetramethylammonium persulfate, urea hydrogen peroxide, and peracetic acid), abrasives (e.g., ceria abrasives, non-ionic abrasives, surface modified abrasives, negatively/positively charged abrasive, or ceramic abrasive composites), silicates, hydroxycarboxylic acids, carboxylic and polycarboxylic acids lacking amino groups, silanes (e.g., alkoxysilanes), cyclic compounds (e.g., cyclic compounds containing at least two rings, such as substituted or unsubstituted naphthalenes, or substituted or unsubstituted biphenylethers), chelating agents (e.g., azoles, diazoles, triazoles, or tetrazoles), buffering agents, corrosion inhibitors (such as azole or non-azole corrosion inhibitors), certain organic acids or their esters (e.g., carboxylic acids or their esters), inorganic acids (e.g., sulfuric acid, sulfurous acid, nitrous acid, nitric acid, phosphorous acid, and phosphoric acid), guanidine, guanidine salts, pyrrolidone, polyvinyl pyrrolidone, salts (e.g., halide salts or metal salts), and catalysts (e.g., metal-containing catalysts).

In some embodiments, the surface treatment compositions described herein can be substantially free of a C₁-C₆ alkanol, a carboxylic acid, a carboxylic acid ester, a Si-containing compound, or water. As used herein, a component that is “substantially free” from a surface treatment composition refers to an ingredient that is not intentionally added into the composition. In some embodiments, the surface treatment compositions described herein can have at most about 1000 ppm (e.g., at most about 500 ppm, at most about 250 ppm, at most about 100 ppm, at most about 50 ppm, at most about 10 ppm, or at most about 1 ppm) of one or more of a component that is substantially free from the etching composition. In some embodiments, the surface treatment compositions described herein can include only two types of components, i.e., the at least one ester and at least one polar organic solvent described herein.

Without wishing to be bound by theory, it is believed that the surface treatment compositions described herein can significantly reduce the number of collapsed pattern features (e.g., having a dimension of at most about 50 nm) on a semiconductor substrate surface during a drying or rinsing step typically used in the semiconductor manufacturing process after the surface is treated by a surface treatment composition described herein.

In some embodiments, the surface treatment methods described herein can further include contacting the surface of a substrate with at least one cleaning solution before contacting the surface with a surface treatment composition. In such embodiments, the at least one cleaning solution can include water, an alcohol, aqueous ammonium hydroxide, aqueous hydrofluoric acid, aqueous hydrochloric acid, aqueous hydrogen peroxide, an organic solvent, or a combination thereof.

In some embodiments, the surface treatment methods described herein can further include contacting the surface of a substrate with a first rinsing solution (e.g., water, an organic solvent such as isopropanol, or a combination thereof) after contacting the surface with the at least one cleaning solution but before contacting the surface with the surface treatment composition. In some embodiments, the surface treatment methods described herein can further include contacting the surface with a second rinsing solution (e.g., water, an organic solvent such as isopropanol, or a combination thereof) after contacting the surface with the surface treatment composition. In some embodiments, the surface treatment methods described herein can further include contacting the surface of a substrate with a third rinsing solution (e.g., water, an organic solvent such as isopropanol, or a combination thereof) after contacting the surface with the first rinsing solution but before contacting the surface with the surface treatment composition. In some embodiments, the surface treatment methods described herein can further include drying the surface (e.g., after any of the steps of contacting the surface with first rinsing solution, the surface treatment composition, or the second rinsing solution).

In some embodiments, this disclosure provides methods for cleaning a semiconductor substrate (e.g., a wafer) having a pattern (e.g., made from Si pillars) disposed on a surface of the substrate. Such methods can be performed, for example, by: a) optionally, contacting the surface with a cleaning solution; b) optionally, contacting the surface with a first rinsing solution and/or a third rinsing solution; c) contacting the surface with a surface treatment composition, wherein the surface treatment composition includes at least one polar organic solvent and at least one ester; d) optionally, contacting the surface with a second rinsing solution; and e) drying the surface. In such embodiments, the pattern can include a feature having a dimension of at most about 50 nm.

In step a) of the above described methods, the substrate (e.g., a wafer) bearing a patterned surface can optionally be treated with one or more cleaning solutions for a suitable period of time (e.g., from 30 seconds to 5 minutes such as 1 minute). When the patterned surface is treated with two or more cleaning solutions, the cleaning solutions can be applied sequentially. The cleaning solutions can be water alone, an organic solvent alone, or can be solutions containing water, a solute, and optionally an organic solvent. In some embodiments, the cleaning solutions can include water, an alcohol (e.g., a water soluble alcohol such as isopropanol), an aqueous ammonium hydroxide solution, an aqueous hydrofluoric acid solution, an aqueous hydrochloric acid solution, an aqueous hydrogen peroxide solution, an organic solvent (e.g., a water soluble organic solvent), or a combination thereof.

In step b), the cleaning solution from step a) can be optionally rinsed away by treating the substrate obtained in step a) with one or more rinsing solutions for a suitable period of time (e.g., from 30 seconds to 5 minutes such as 1 minute). When the substrate is treated with two or more rinsing solutions, the rinsing solutions can be applied sequentially. The rinsing solutions (e.g., the first and third rinsing solutions mentioned herein) can include water, an organic solvent (e.g., isopropanol), or an aqueous solution containing an organic solvent. In some embodiments, the rinsing solutions are at least partially miscible with the cleaning solution used in step a). In some embodiments, step b) can be omitted when the cleaning solution used in step a) is not moisture sensitive or does not contain any appreciable amount of water.

In step c), the substrate surface can be treated with a surface treatment composition described herein. The surface thus treated can have an increased water contact angle of. In some embodiments, the contact angle can be at least about 50 degrees (e.g., at least about 55 degrees, at least about 60 degrees, at least about 65 degrees, at least about 70 degrees, at least about 75 degrees, at least about 80 degrees, at least about 85 degrees, at least about 90 degrees, at least about 95 degrees, or at least about 100 degrees) and/or at most about 175 degrees. In some embodiments, this step can be performed at a temperature of about 20-35° C. for a process time ranging from about 10 seconds to about 300 seconds.

In step d), after the substrate surface is treated with a surface treatment composition, the surface can be rinsed with a second rinsing solution. The second rinsing solution can include water, an organic solvent (e.g., isopropanol), or an aqueous solution containing an organic solvent. In some embodiments, this step can be performed at a temperature of about 20-70° C.

In step e), the substrate surface can be dried (e.g., by using a pressurized gas). Without wishing to be bound by theory, it is believed that, after the substrate surface is treated with a surface treatment composition described herein, the collapse of patterns on the surface during this drying step is minimized. For example, the surface thus treated can have at least about 50% (e.g., at least about 55%, at least about 60%, at least about 65%, at least about 70%, at least about 75%, at least about 80%, at least about 85%, or at least about 90%) or at most about 99% uncollapsed patterns after step (e) relative to the total number of patterns on the surface.

The semiconductor substrate having a cleaned, patterned surface prepared by the method described above can be further processed to form one or more circuits on the substrate or can be processed to form into a semiconductor device (e.g., an integrated circuit device such as a semiconductor chip) by, for example, assembling (e.g., dicing and bonding) and packaging (e.g., chip sealing).

In some embodiments, this disclosure features articles (e.g., an intermediate semiconductor article formed during the manufacturing of a semiconductor device) that includes a semiconductor substrate, and a surface treatment composition described herein supported by the semiconductor substrate. The surface treatment composition can include at least one polar organic solvent and at least one ester, as described above.

The present disclosure is illustrated in more detail with reference to the following examples, which are for illustrative purposes and should not be construed as limiting the scope of the present disclosure.

### Example 1

Surface Treatment Solutions (i.e., formulations 1-20) are prepared by mixing the components at room temperature. The compositions of formulations 1-20 are summarized in Table 1 below. All percentages listed in Table 1 are weight percentages, unless indicated otherwise.

### Contact Angle Measurement

Semiconductor substrates containing SiO₂ films are treated with formulations 1-20 and the contact angles of the treated surfaces are measured as follows. The coupons containing SiO₂ films on Si substrates are cut into 1×1 inch squares and then rinsed sequentially with 1 wt % aqueous hydrofluoric acid for 30 seconds, deionized water for 60 seconds, and isopropanol for 60 seconds at room temperature. The coupons are immersed vertically into 100 mL of stirred (50 RPM) Surface Treatment Solutions and are kept at room temperature for 30 seconds. The coupons are then rinsed with isopropanol at 50° C. for 60 seconds and dried by using pressurized nitrogen gas.

The coupons are placed on the AST VCA 3000 Contact Angle Tool and the following procedure is followed to measure the contact angles:
1. Place the SiO₂ coupon onto the stage.
2. Raise the stage upward by rotating Vertical Knob clockwise until the specimen is just below the needle.
3. Dispense a drop of De-ionized water, lightly touching the specimen surface, then lower the specimen until the droplet separates from the needle tip.
4. Center the drop across the field-of-view using transverse knob for stage adjustment.
5. Focus the drop in field-of-view to get a sharp image by moving the stage along guide rails.
6. Click the “AutoFAST” button to freeze the image and calculate. Two numbers will be displayed; these are the left and right contact angles.
7. To calculate manually, use the mouse to place five markers around the droplet.
8. Select the droplet icon from the Main Menu to calculate the contact angle.
9. This will create a curve fit and tangent lines on the image. Two numbers will be displayed in the left-hand-corner of the screen; these are the left and right contact angles.
10. Repeat above procedure at 3 substrate sites and average the resulting contact angles.

### Pattern Collapse Measurement

Patterned wafers are treated with surface treatment compositions, i.e., formulations 1-20. High aspect ratio Si pillar patterned wafers are diced into 0.5 inch by 0.5 inch coupons. The coupons are then immersed into stirred surface treatment compositions for 30-180 seconds at 25° C. The coupons are removed from the surface treatment compositions and rinsed in a beaker containing stirred isopropyl alcohol for 60 seconds at 50° C. The coupons are then removed from the Isopropyl alcohol and dried with a N₂ gas dispense gun oriented perpendicularly to the coupon at a working distance of 1 inch with gas pressure of 45 psi. The coupons are then analyzed by scanning electron microscopy over three randomly selected sites at a magnification of 50000× and the number of uncollapsed silicon pillars are tabulated. The average of uncollapsed Si-pillars at the three sites are calculated as a percentage of the total Si pillars observed.

TABLE 1

| | | | Liquid |
|---|---|---|---|
| Form. | | | Appear- |
| # | Ester(s) | Solvent(s) | ance |
| 1 | 1% Diethyl hydrogen phosphate | 99% Isopropyl alcohol | Clear |
| 2 | 3% Diethyl hydrogen phosphate | 97% Isopropyl alcohol | Clear |
| 3 | 5% Diethyl hydrogen phosphate | 95% Isopropyl alcohol | Clear |
| 4 | 8% Diethyl hydrogen phosphate | 92% Isopropyl alcohol | Clear |
| 5 | 1% Diethyl hydrogen phosphate | 99% Butanone | Clear |
| 6 | 3% Diethyl hydrogen phosphate | 97% Butanone | Clear |
| 7 | 5% Diethyl hydrogen phosphate | 95% Butanone | Clear |
| 8 | 8% Diethyl hydrogen phosphate | 92% Butanone | Clear |
| 9 | 1% Triethyl phosphate | 99% Isopropyl alcohol | Clear |
| 10 | 3% Triethyl phosphate | 97% Isopropyl alcohol | Clear |
| 11 | 5% Triethyl phosphate | 95% Isopropyl alcohol | Clear |
| 12 | 8% Triethyl phosphate | 92% Isopropyl alcohol | Clear |
| 13 | 1% Diethyl Sulfate | 99% Isopropyl alcohol | Clear |
| 14 | 3% Diethyl Sulfate | 97% Isopropyl alcohol | Clear |
| 15 | 5% Diethyl Sulfate | 95% Isopropyl alcohol | Clear |
| 16 | 8% Diethyl Sulfate | 92% Isopropyl alcohol | Clear |
| 17 | 1% ethyl methanesulfonate | 99% Isopropyl alcohol | Clear |
| 18 | 3% ethyl methanesulfonate | 97% Isopropyl alcohol | Clear |
| 19 | 5% ethyl methanesulfonate | 95% Isopropyl alcohol | Clear |
| 20 | 8% ethyl methanesulfonate | 92% Isopropyl alcohol | Clear |

It is expected that the contact angles of the substrates treated by formulations 1-would range from about 50 degrees to 97 degrees, and the percentage of uncollapsed patterns on the substrates treated by formulations 1-20 would range from about 50% to about 95%.

While the invention has been described in detail with reference to certain embodiments thereof, it will be understood that modifications and variations are within the spirit and scope of that which is described and claimed.

What is claimed is:

1. A method for treating a semiconductor substrate having a pattern disposed on a surface of the wafer, comprising:
contacting the surface with a surface treatment composition comprising at least one polar organic solvent and at least one ester selected from the group consisting of sulfonic acid esters, sulfuric acid esters, and phosphoric acid esters;
wherein the pattern comprises a feature having a dimension of at most about 50 nm.

2. The method of claim 1, wherein the least one polar organic solvent comprises an alcohol, a ketone, a lactone, or a sulfoxide.

3. The method of claim 2, wherein the at least one polar organic solvent comprises isopropyl alcohol, acetone, butanone, butyrolactone, or DMSO.

4. The method of claim 1, wherein the at least one polar organic solvent is in an amount of from about 90 wt % to about 99 wt % of the composition.

5. The method of claim 1, wherein the at least one ester comprises (RO)ₙ(HO)₃₋ₙP═O, R(SO₂)(OR), or (RO)ₙ(HO)₂₋ₙ(SO₂), in which each n independently is 1 or 2, and each R independently is C₁-C₁₀ alkyl, phenyl, or C₇-C₁₀ arylalkyl.

6. The method of claim 1, wherein the at least one ester comprises dimethyl sulfate, diethyl sulfate, ethyl methanesulfonate, ethyl benzenesulfonate, ethyl dihydrogen phosphate, diethyl hydrogen phosphate, or triethyl phosphate.

7. The method of claim 1, wherein the at least one ester is in an amount of from about 1 wt % to about 10 wt % of the composition.

8. The method of claim 1, wherein the surface treatment composition is substantially free of a C₁-C₆ alkanol, a carboxylic acid, a carboxylic acid ester, a Si-containing compound, or water.

9. The method of claim 1, wherein the surface treatment composition consists of the at least one polar organic solvent and the at least one ester.

10. The method of claim 1, further comprising contacting the surface with at least one cleaning solution before contacting the surface with the surface treatment composition.

11. The method of claim 10, wherein the at least one cleaning solution comprise water, an alcohol, aqueous ammonium hydroxide, aqueous hydrofluoric acid, aqueous hydrochloric acid, aqueous hydrogen peroxide, an organic solvent, or a combination thereof.

12. The method of claim 10, further comprising contacting the surface with a first rinsing solution after contacting the surface with the at least one cleaning solution but before contacting the surface with the surface treatment composition.

13. The method of claim 12, further comprising contacting the surface with a second rinsing solution after contacting the surface with the surface treatment composition.

14. The method of claim 1, further comprising drying the surface.

15. The method of claim 1, wherein the surface comprises SiO₂, SiN, TiN, SiOC, SiON, Si, SiGe, Ge, Ru, Ta, TaO, TaON, or W.

16. The method of claim 1, wherein the pattern comprises a patterned developed photoresist layer, a patterned barrier layer, a patterned multi-stack layer, or a patterned dielectric layer.

17. The method of claim 1, further comprising forming a semiconductor device.

18. The method of claim 17, wherein the semiconductor device comprises an integrated circuit device.

19. A composition, comprising:
at least one polar organic solvent in an amount of from about 90 wt % to about 99 wt % of the composition; and
at least one ester selected from the group consisting of nitric acid esters, sulfonic acid esters, and phosphoric acid esters, the at least one ester being in an amount of from about 1 wt % to about 10 wt % of the composition.

20. The composition of claim 19, wherein the least one polar organic solvent comprises an alcohol, a ketone, a lactone, or a sulfoxide.

21. The composition of claim 20, wherein the at least one polar organic solvent comprises isopropyl alcohol, acetone, butanone, butyrolactone, or DMSO.

22. The composition of claim 19, wherein the at least one ester comprises (RO)ₙ(HO)₃₋ₙP═O, R(SO₂)(OR), or (RO)ₙ(HO)₂₋ₙ(SO₂), in which each n independently is 1 or 2, and each R independently is C₁-C₁₀ alkyl, phenyl, or C₇-C₁₀ arylalkyl.

23. The composition of claim 19, wherein the at least one ester comprises dimethyl sulfate, diethyl sulfate, ethyl methanesulfonate, ethyl benzenesulfonate, ethyl dihydrogen phosphate, diethyl hydrogen phosphate, or triethyl phosphate.

24. A composition, consisting of:
at least one polar organic solvent; and
at least one ester selected from the group consisting of nitric acid esters, sulfonic acid esters, and phosphoric acid esters.
